(19) United States
(12) Patent Application Publication
(10) Pub. No.: US 2010/0090323 A1
(43) Pub. Date: Apr. 15, 2010

(54) COMPOSITE TYPE SEMICONDUCTOR DEVICE SPACER SHEET, SEMICONDUCTOR PACKAGE USING THE SAME, COMPOSITE TYPE SEMICONDUCTOR DEVICE MANUFACTURING METHOD, AND COMPOSITE TYPE SEMICONDUCTOR DEVICE

(75) Inventors: Tomonori Shinoda, Saitama (JP); Hironori Shizuhata, Tokyo (JP); Hirofumi Shinoda, Kanagawa (JP); Yuji Kawamata, Tokyo (JP); Takeshi Tashima, Tokyo (JP); Masato Shimamura, Tokyo (JP); Masako Watanabe, Oita (JP); Masazumi Amagai, Ibaraki (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Lintec Corporation, Itabashi-ku (JP)

(21) Appl. No.: 12/446,813

(22) PCT Filed: Oct. 22, 2007
(86) PCT No.: PCT/JP07/70562

§ 371 Date: Apr. 23, 2009

(30) Foreign Application Priority Data
Oct. 24, 2006 (JP) 2006-289066

(51) Int. Cl. H01L 23/52; H05K 7/00; H01L 21/60

(52) U.S. Cl. 257/686; 174/138 G; 438/107; 257/690; 438/121; 257/E21.511; 257/E23.141

(57) ABSTRACT

The present invention provides a spacer sheet for a complex type semiconductor device provided between the semiconductor packages of a complex type semiconductor device formed by laminating plural semiconductor packages, comprising through holes of an array corresponding to electrodes which can be provided onto a substrate of one semiconductor package and which are formed in order to connect and wire one semiconductor package with the other semiconductor package and a space part corresponding to a principal part of the above one semiconductor package mounted on the substrate or a principal part of the other semiconductor package opposed to the substrate and a production process for a complex type semiconductor device in which the above spacer sheet is used. It further provides a wiring and connecting method by using a spacer sheet which satisfies securing of a distance between connection terminals and a narrow pitch at the same time in a POP type semiconductor package and a complex type semiconductor device of a POP type which is increased in a packaging density by the above wiring and connecting method.

### BACKGROUND OF THE INVENTION

The present invention relates to a spacer sheet disposed between semiconductor packages in order to secure conduction of a semiconductor package to an external electrode and an installation space of a semiconductor package in a complex type semiconductor device of a POP (package-on-package) type comprising combination of plural semiconductor packages, a semiconductor package prepared by using the same, a production process for a complex type semiconductor device and a complex type semiconductor device obtained by the above production process.

### RELATED ART

In the semiconductor field, when a device is prepared by combining semiconductor chips having different circuits into one system, available are two techniques of SiP (system-in-package) in which another semiconductor chip is mounted on a semiconductor chip to obtain one package and POP in which plural semi-completed semiconductor chips are directly connected. SiP has the merits that since circuits are directly connected, power consumption is low and that circuit operation is quick.

In contrast with this, since POP is produced from a semi-completed package, combination of packages which are proved to be good items by quality inspection can be selected, and a yield of the completed device is not lowered. Further, POP is completed in a final mounting step, and therefore involved therein is the merit that instrument producers themselves can select combinations of semiconductor devices which exert performances meeting the features of the products, which is not expected from finished semiconductor devices.

On the other hand, POP prepared by combining peripheral terminal type semiconductor packages themselves such as QFP (quad flatpack package) and the like can be mounted on a mother board by arranging a length of a peripheral terminal with a position of the other peripheral terminal. In contrast with this, in combination of grid terminal type semiconductor packages themselves such as BGA (ball grid array) and the like, not only terminals arranged on a lower surface interrupt connection of the semiconductor packages, but also the problem that it is difficult to secure a conduction passage of an upper semiconductor package with a mother board is involved therein.

Accordingly, put to practical use are POP type semiconductor packages comprising a structure in which a size of a principal part in a lower semiconductor package is reduced more than a size of a substrate (interposer) in upper and lower semiconductor packages and in which both semiconductor packages are connected to an outer circumference of the principal part in the lower semiconductor package by a conducting material for conducting the upper and lower substrates (refer to, for example, patent documents 1 to 5).

In the semiconductor device of the above POP system, a chip lamination number of a semiconductor package represented by BGA and the like which is positioned in a lower part in lamination tends to grow larger in order to raise more a packaging density.

A resin mold (thermosetting polymer molded matter) for protecting chips is increased in a height due to an increase in a lamination number, and a larger distance between substrates than the height has to be maintained. A method therefor includes a) enlarging a connection terminal in order to increase a connection terminal distance between upper and lower semiconductor packages so that it meets a thickness of the lower semiconductor package and b) controlling a mold height of the lower semiconductor package to a lower level by a reduction in a size of the chip and an increase in a density thereof.

However, if a connection terminal is increased in a size under an existing situation in which a pitch between connection terminals has to be narrowed by an increase in pins, short between adjacent connection terminals themselves is caused. Further, a decrease in the thicknesses of a chip and a substrate brings about an increase in the cost to a large extent.

Accordingly, a connecting method having a low cost and a high reliability which can satisfy a height of a connection terminal distance and a narrow pitch thereof at the same time is required.

Patent document 1: Japanese Patent Application Laid-Open No. 319775/2004
Patent document 2: Japanese Patent Application Laid-Open No. 72190/2005
Patent document 3: Japanese Patent Application Laid-Open No. 197370/2005
Patent document 4: Japanese Patent Application Laid-Open No. 311066/2005
Patent document 5: Japanese Patent Application Laid-Open No. 340451/2005

### DISCLOSURE OF THE INVENTION

The present invention is to solve the problem described above, and an object thereof is to provide a wiring and connecting method by a spacer sheet which satisfies securement of a height of a connection terminal distance and a narrow pitch thereof at the same time in a POP type semiconductor package and allow a complex type semiconductor device of a POP type having a high packaging density to be provided by the above method.

Intensive researches repeated by the present inventors in order to achieve the object described above have resulted in finding that the object can be achieved by using a specific spacer sheet between substrates. The present invention has been completed based on the above knowledge.

That is, the essential points of the present invention are:

1. a spacer sheet for a complex type semiconductor device provided between the semiconductor packages of a complex type semiconductor device formed by laminating plural semiconductor packages, comprising through holes of an array corresponding to electrodes which can be provided onto a substrate of one semiconductor package and which are formed on the above substrate in order to connect and wire one semiconductor package with the other semiconductor package and a space part corresponding to a principal part of the above one semiconductor package mounted on the substrate or a principal part of the other semiconductor package opposed to the substrate,
2. the spacer sheet for a complex type semiconductor device according to the above item 1, wherein the through holes of the spacer sheet are cone-shaped,
3. a sheet material used for the spacer sheet for a complex type semiconductor device according to the above item 1 or 2,
4. a semiconductor package used for a complex type semiconductor device formed by laminating plural semiconductor packages, comprising a principal part of the above semiconductor package, a substrate on which the above principal part is mounted and which has a broader area than that of the principal part, an electrode provided on a surface of the above substrate at a side which is connected and wired with the other semiconductor package, a spacer sheet which has through holes of an array corresponding to the above electrode and which is adhered on a surface of the above substrate at a side connected and wired with the other semiconductor package and a connection terminal provided on the above electrode in the state that it is inserted into the through hole,
5. a production process for a complex type semiconductor device formed by laminating plural semiconductor packages, comprising:
a step in which a connection terminal is formed on an electrode provided on a substrate of one semiconductor package and used for conducting with the other semiconductor package, a step in which through holes in an array corresponding to the electrodes and a space part corresponding to a principal part of the one semiconductor package mounted on the substrate or a principal part of the other semiconductor package opposed to the above substrate are provided on a sheet material capable of being adhered onto the above substrate to prepare a spacer sheet,
a step in which the spacer sheet is opposed to the substrate and in which the respective through holes and the space part of the spacer sheet are fitted to the positions of the electrodes and the position of the principal part of the one semiconductor package mounted on the substrate or the principal part of the other semiconductor package opposed to the substrate to adhere the spacer sheet to the substrate, a step in which a connection terminal is formed on the electrode of the substrate in the other semiconductor package and
a step in which the connection terminal of the substrate in the one semiconductor package is fused with the connection terminal of the substrate in the other semiconductor package,
6. the production process according to the above item 5, wherein the through holes are provided in a cone shape and
7. a complex type semiconductor device produced by the production process according to the above item 5 or 6.

According to the present invention, a wiring and connecting method by a spacer sheet which satisfies securement of a height of a connection terminal distance and a narrow pitch thereof at the same time in a POP type semiconductor package has been able to be provided, and this has made it possible to provide a complex type semiconductor device of a POP type having a high packaging density.

### BRIEF DESCRIPTIONS OF THE DRAWINGS

FIG. 1 is a cross-sectional schematic drawing showing one example of a conventional complex type semiconductor device.

FIG. 2 is a cross-sectional schematic drawing showing one example of the complex type semiconductor device of the present invention.

FIG. 3 is a cross-sectional schematic drawing showing another example of the complex type semiconductor device of the present invention.

FIG. 4 is a cross-sectional schematic drawing showing the spacer sheet of the present invention.

FIG. 5 is a cross-sectional schematic drawing showing another spacer sheet of the present invention.

FIG. 6 is a cross-sectional schematic drawing showing another spacer sheet of the present invention.

FIG. 7 is a plain schematic drawing showing the spacer sheet of the present invention after providing through holes.

FIG. 8 is a plain schematic drawing showing the spacer sheet of the present invention after punching work of a pattern.

FIG. 9 is a step schematic drawing in the production process of the present invention.

FIG. 10 is a step schematic drawing showing another example of the production process of the present invention.

FIG. 11 is a cross-sectional schematic drawing showing another one example of the complex type semiconductor device of the present invention.

FIG. 12 is a cross-sectional schematic drawing showing another one example of the complex type semiconductor device of the present invention.

FIG. 13 is a cross-sectional schematic drawing showing another one example of the complex type semiconductor device of the present invention.

FIG. 14 is a cross-sectional schematic drawing showing another one example of the complex type semiconductor device of the present invention.

### EXPLANATIONS OF THE CODES

1 Conventional complex type semiconductor device of a POP type
10 Complex type semiconductor device of a POP type according to the present invention
11 Lower semiconductor package having a low packaging density
12 Upper semiconductor package
13 Lower semiconductor package having a high packaging density
14 Wiring connecting part (conventional)
15 Wiring connecting part (present invention)
21 Flip chip
100 Spacer sheet
101, 101a, 101b Adhesive layer
102, 102a, 102b Base material layer
103 Through hole
104 Release film
105 Space part
111 Substrate
116 Principal part of lower semiconductor package having a low packaging density
121 Substrate
122 Electrode
123 Semiconductor chip aa
124 Semiconductor chip ab
125 Bonding wire
126, 126a, 126b Principal part of upper semiconductor package
131 Substrate
132 Electrode
133 Semiconductor chip ba
134 Semiconductor chip bb
135 Bonding wire
136 Lower semiconductor package having a high packaging density
140, 141, 142 Connection terminal

### BEST MODE FOR CARRYING OUT THE INVENTION

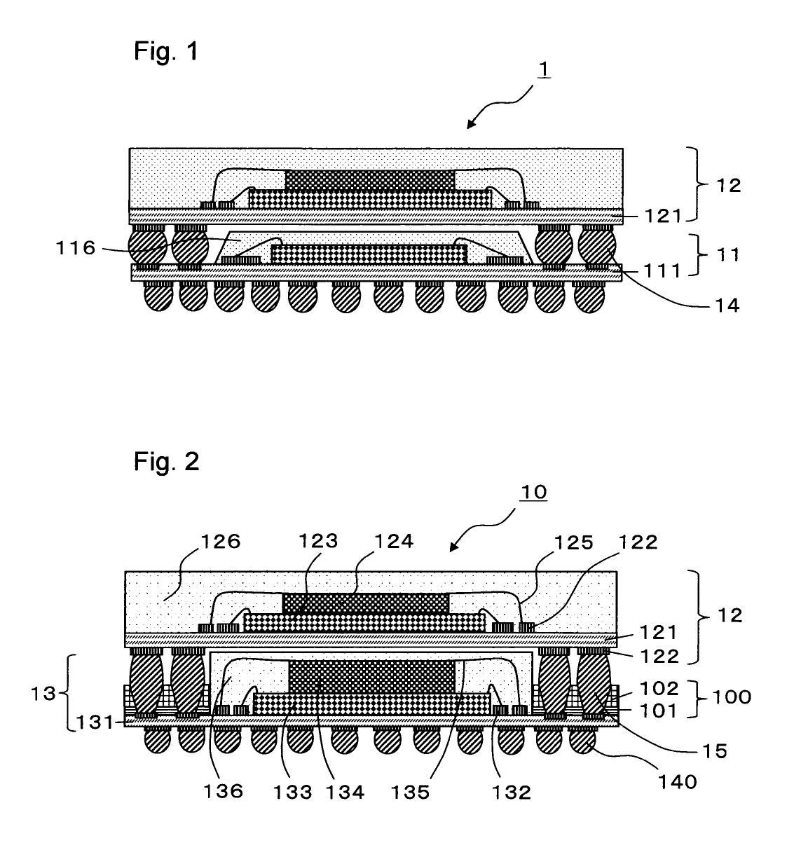

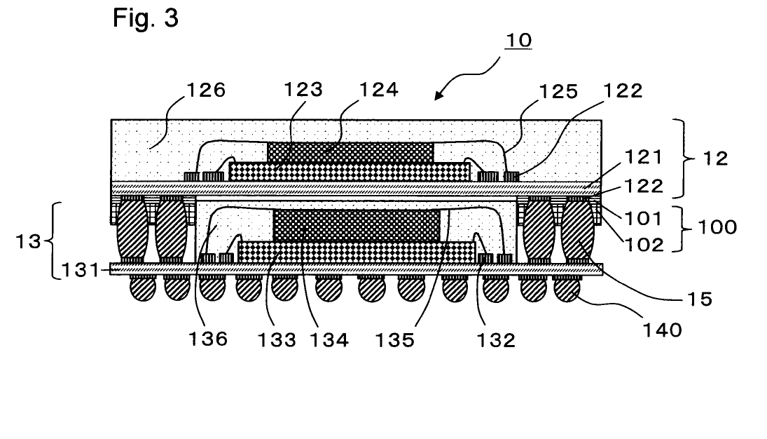

The spacer sheet of the present invention and the complex type semiconductor device of the present invention obtained by the production process for a complex type semiconductor device carried out by using the same shall be explained with reference to the drawings. FIG. 1 is a cross-sectional schematic drawing showing one example of a conventional complex type semiconductor device; FIG. 2 is a cross-sectional schematic drawing showing one example of the complex type semiconductor device of a POP type according to the present invention; and FIG. 3 is a cross-sectional schematic drawing showing another example of the complex type semiconductor device of the present invention.

In FIG. 1, a conventional complex type semiconductor device 1 of a POP type is prepared by laminating an upper semiconductor package 12 on a lower semiconductor package 11 having a low packaging density via a wiring connecting part 14. Since the lower semiconductor package 11 has a low packaging density, a principal part 116 thereof has a low height, and a spacing between a substrate 111 which is an interposer of the lower semiconductor package 11 and a substrate 121 which is an interposer of the upper semiconductor package 12 is narrow, and a pitch of the wiring connecting part 14 is wide. Therefore, one ordinary solder ball is used as the wiring connecting part 14, and the wiring connecting part 14 is approximately spherical.

In contrast with this, the complex type semiconductor device 10 of a POP type according to the present invention is prepared, as shown in FIG. 2, by laminating an upper semiconductor package 12 on a lower semiconductor package 13 having a high packaging density via a wiring connecting part 15 having a vertically long rotator shape, particularly a vertically long spindle shape or an ellipsoidal shape. The upper semiconductor package 12 comprises a semiconductor chip aa 123, a semiconductor chip ab 124, bonding wires 125, a substrate 121 which is an interposer and electrodes 122 provided thereon and a principal part 126 comprising a thermosetting polymer molding which seals the above members. The lower semiconductor package 13 comprises a semiconductor chip ba 133, a semiconductor chip bb 134, bonding wires 135, a substrate 131 which is an interposer and an electrode 132 provided thereon and a principal part 136 comprising a thermosetting polymer molding which seals the above members. In this connection, the wiring connecting part 15 having a vertically long rotator shape makes connecting and wiring possible even if a spacing between the substrate 121 which is an interposer of the upper semiconductor package 12 and the substrate 131 which is an interposer of the lower semiconductor package 13 is wide, and it does not bring about short circuit even if a pitch between the adjacent wiring connecting parts 15 is narrow. In a spacer sheet 100, a solder ball is formed so that the above wiring connecting part 15 assumes a vertically long rotator shape, and in FIG. 2, the spacer sheet comprises an adhesive layer 101 and a base material layer 102.

FIG. 3 shows another example of the complex type semiconductor device 10 of a POP type according to the present invention and is different in the point that a spacer sheet 100 is adhered on a substrate 121 which is an interposer of an upper semiconductor package 12, and a wiring connecting part 15 assumes a vertically long rotator shape, whereby the same effect as in a case of FIG. 2 is exerted.

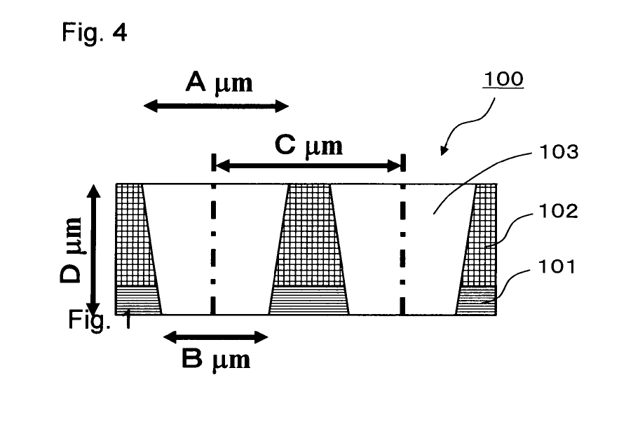

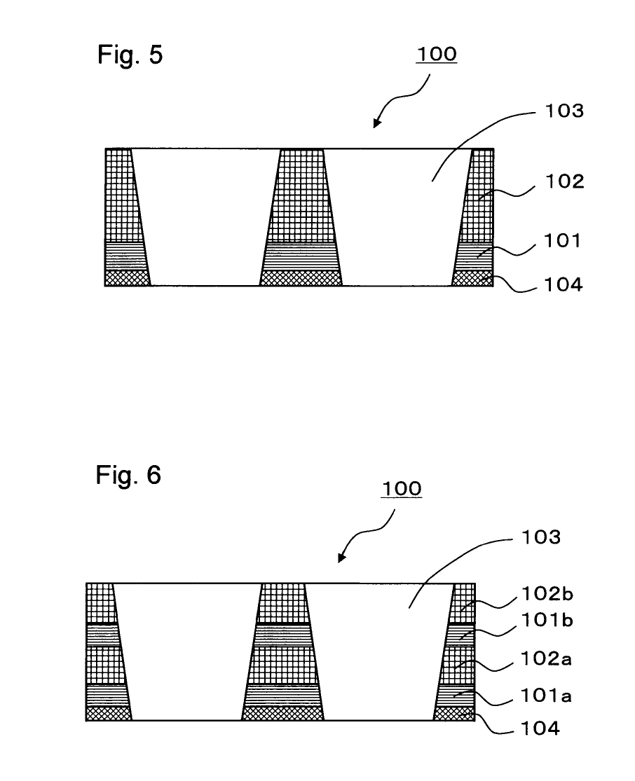

Next, the spacer sheet 100 of the present invention shall be explained with reference to FIGS. 4 to 6. FIG. 4 is a cross-sectional schematic drawing showing the spacer sheet of the present invention, and FIGS. 5 and 6 are cross-sectional schematic drawings showing another spacer sheets of the present invention.

FIG. 4 shows an example of a two layer structure comprising a sheet material of an adhesive layer 101 and a base material layer 102 which is a typical layer structure of the spacer sheet 100 of the present invention. The spacer sheet 100 has preferably a group of cone-shaped through holes 103. The through holes 103 have a through hole maximum diameter A of preferably 100 to 500 μm at an upper side and a through hole minimum diameter B of preferably 100 to 500 μm at a lower side, and a ratio (A/B) of A to B is preferably 1 to 2. A pitch C of the through holes 103 depends on an electrode constitution of the semiconductor package used, and a thickness D of the spacer sheet 100 depends on a thickness of the semiconductor package used. C is preferably 30 to 2000 μm, and D is preferably 50 to 500 μm.

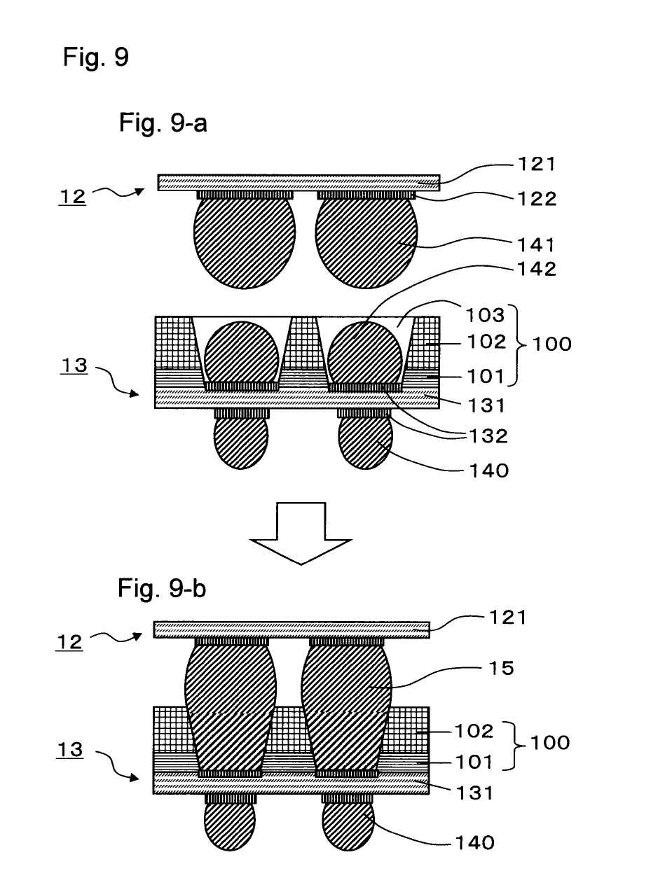

As shown in FIG. 9-a described later, the through hole maximum diameter A is disposed preferably at a side opposite to the substrate, and the through hole minimum diameter B is disposed preferably at a substrate side. The above disposition prevents constriction at a wiring connecting part 15 which is formed by fusing connection terminals 141 and 142 described later, and therefore an impact resistance of the complex type semiconductor device is enhanced.

A means for forming the through holes 103 includes laser processing, drill processing, punching and the like. Among them, laser processing carried out by using a carbon dioxide gas laser, a YAG laser, an excimer laser and the like is preferred since the through holes 103 having a high degree of precession are formed.

FIG. 5 shows an example in which used is a sheet material provided thereon with a release film 104 for protecting a surface before sticking an adhesive layer 101, and FIG. 6 shows an example in which used is a sheet material comprising a five layer structure of a release film 104, an adhesive layer 101a, a base material layer 102a, an adhesive layer 101b and a base material layer 102b from the bottom. The sheet material used for the spacer sheet 100 of the present invention has preferably at least a structure in which it can be adhered on the substrate. To be typical, the spacer sheet 100 comprises, as described above, two layers of the adhesive layer 101 and the base material layer 102, and when the spacer sheet is increased in a thickness, the spacer sheet may be prepared from a sheet material of such a four layer or six layer as prepared by laminating the above sheet materials of a two layer. Further, when an adhesive in which a strength can suitably be changed by curing after stuck on a substrate is used as is the case with a thermosetting adhesive described later, the spacer sheet may be prepared from a sheet material having only one adhesive layer.

The release film 104 is peeled and removed immediately before the spacer sheet 100 of the present invention is stuck on a substrate 121 or a substrate 131, and it may be further provided, if necessary, on the surface of the base material layer 102. In particular, when the sheet material used for the spacer sheet 100 comprises only one layer of the adhesive layer 101, the release film 104 is preferably provided on both surfaces thereof in order to protect the surface of the adhesive layer 101.

The adhesive layer 101 in the sheet material used for the spacer sheet 100 of the present invention is preferably a layer showing a strong adhesive property to the substrate. And it comprises preferably a resin composition containing at least one resin selected from the group consisting of (meth)acrylic resins, silicone resins, epoxy resins, polyimide resins, maleimide resins, bismaleimide resins, polyamideimide resins, polyetherimide resins, polyimide-isoindroxonazolinedioneimide resins, polyvinyl acetate resins, polyvinyl alcohol resins, polyvinyl chloride resins, polyacrylic ester resins, polyamide resins, polyvinyl butyral resins, polyethylene resins, polypropylene resins and polysulfone resins. The adhesive layer comprising the above resins may be pressure-sensitive adhesive (sticky) or non-pressure-sensitive adhesive at ambient temperature. Further, it may be either thermoplastic or thermosetting. A thickness of the adhesive layer (single layer) 101 of a side which is stuck to the substrate is preferably 10 to 200 μm.

A (meth)acrylic resin composition can be turned into either a pressure-sensitive adhesive or a non-pressure-sensitive adhesive. Compositions in which copolymers obtained by copolymerizing various (meth)acrylic ester monomers with copolymerizable monomers blended if necessary are used as principal raw materials and in which additives such as a cross-linking agent and others are suitably blended are suitably used as the (meth)acrylic resin composition for a pressure-sensitive adhesive. In this connection, (meth)acrylic means acrylic or methacrylic.

Used as the (meth)acrylic ester monomers are, for example, acrylic alkyl esters such as methyl acrylate, ethyl acrylate, butyl acrylate, 2-ethylhexyl acrylate, octyl acrylate, cyclohexyl acrylate, benzyl acrylate and the like and methacrylic alkyl esters such as butyl methacrylate, 2-ethylhexyl methacrylate, cyclohexyl methacrylate, benzyl methacrylate and the like.

Vinyl acetate, vinyl propionate, vinyl ethers, styrene and acrylonitrile are used as the copolymerizable monomers, for example, as the monomers having no functional groups.

Suitably used as the copolymerizable monomers having functional groups are, for example, carboxyl group-containing monomers such as acrylic acid, methacrylic acid, crotonic acid, maleic acid, fumaric acid, itaconic acid and the like, hydroxyl group-containing monomers such as 2-hydroxyethyl (meth)acrylate, 2-hydroxypropyl (meth)acrylate, 2-hydroxybutyl (meth)acrylate, N-methylolacrylamide, allyl alcohol and the like, tertiary amino group-containing monomers such as dimethylaminopropyl (meth)acrylate and the like, N-substituted amide group-containing monomers such as acrylamide, N-methyl(meth)acrylamide, N-methoxymethyl(meth)acrylamide, N-octylacrylamide and the like and epoxy group-containing monomers such as glycidyl methacrylate and the like.

The cross-linking agents used for the (meth)acrylic resin composition include isocyanate compounds, epoxy compounds, metal chelate compounds, amine compounds, hydrazine compounds, aldehyde compounds, metal alkoxide compounds, metal salts and the like. Among them, the isocyanate compounds and the epoxy compounds are preferred.

A silicone resin composition can be turned as well into either a pressure-sensitive adhesive or a non-pressure-sensitive adhesive. The silicone resin composition which is turned into a pressure-sensitive adhesive is constituted usually from a base adhesive comprising a mixture of a silicone resin component and a silicone gum component and additives such as a cross-linking agent, a catalyst and the like. The silicone resin composition includes an addition reaction type composition, a condensation reaction type composition, a peroxide cross-linking type composition and the like according to a cross-linking system, and addition reaction type silicone resin compositions are preferred in terms of a productivity and the like. The addition reaction type silicone resin composition is cross-linked by a silicone gum component or a silicone resin component which contains a vinyl group and in which a hydrosilyl group (SiH group) is a cross-linking site. Further, the addition reaction type silicone resin composition is blended, if necessary, with a catalyst for accelerating the reaction, such as a platinum catalyst and the like.

A polyimide resin is usually non-pressure-sensitive adhesive and thermoplastic, and therefore it can be adhered by bringing into tight contact with the substrate and heating. The polyimide resin is preferably an aliphatic polyimide resin having a good heating adhesive property.

An epoxy resin alone is non-pressure-sensitive adhesive, and it is thermosetting due to a reactivity of an oxirane ring. Bisphenol A type epoxy resins, o-cresol novolac type epoxy resins and the like are preferred as the epoxy resin, and they are used usually in the form of a thermosetting resin composition prepared by blending them with a curing agent such as dicyandiamide and the like and a curing accelerating agent such as 2-phenyl-4,5-hydroxymethylimidazole and the like. Thus, the compositions of the epoxy resins are used as thermosetting resin compositions.

Thermosetting type pressure-sensitive adhesives can be used as the adhesive layer 101 used in the present invention. The thermosetting type pressure-sensitive adhesive can be used usually by blending a pressure-sensitive adhesive and a thermosetting adhesive. For example, a blended matter of the (meth)acrylic resin composition and the epoxy resin each described above is preferred.

The base material layer 102 of the sheet material used for the spacer sheet 100 of the present invention is preferably a layer having a dimensional stability, a handling aptitude and a processing aptitude and fulfilling a performance to maintain the thickness, and the layer having a high mechanical strength is preferred. A melting point of the base material layer 102 or a thermal decomposition temperature of the base material layer 102 having no melting point is preferably 150° C. or higher, more preferably 200° C. or higher. A high dimensionally stable and heat resistant film of a polyimide resin, particularly an aromatic polyimide resin, a polyethylene terephthalate resin, a polyethylene naphthalate resin, a polymethylpentene resin, a fluororesin, a liquid crystal polymer, a polyetherimide resin, an aramid resin, a polyetherketone resin, a polyphenylene sulfide resin and the like is suitably used for the base material layer 102. A mechanical strength of the base material layer 102 is preferably 100 MPa or more in terms of a Young's modulus at room temperature. A thickness of the base material layer 102 is suitably selected according to a thickness of the spacer sheet 100 desired.

The release film 104 of the sheet material used for the spacer sheet 100 of the present invention is releasably laminated on the surface of the adhesive layer 101 in the spacer sheet 100 to protect the surface of the adhesive layer 101 from adhesion of foreign matters, scratching and deformation. A film on which a release agent such as a silicone resin, an alkyd resin and the like is applied is suitably used as the release film 104, and particularly a polyethylene terephthalate film and a polyethylene naphthalate film which are subjected to release treatment are preferred. A thickness of the release film 104 is preferably 10 to 200 μm. The adhesive layer 101 in the spacer sheet 100 can be prevented from being stained by providing the release film 104, and it becomes easy to handle.

A carrier film used in forming the adhesive layer 101 may be laminated as it is and diverted to the release film.

The spacer sheet 100 of the present invention is insulating since it is brought into contact with many connection terminals, and it has preferably a volume resistivity of 10¹² Ω·cm or more. The adhesive layer and the base material layer of the sheet material used for the spacer sheet 100 of the present invention are insulating as well, and they each have preferably a volume resistivity of 10¹² Ω·cm or more.

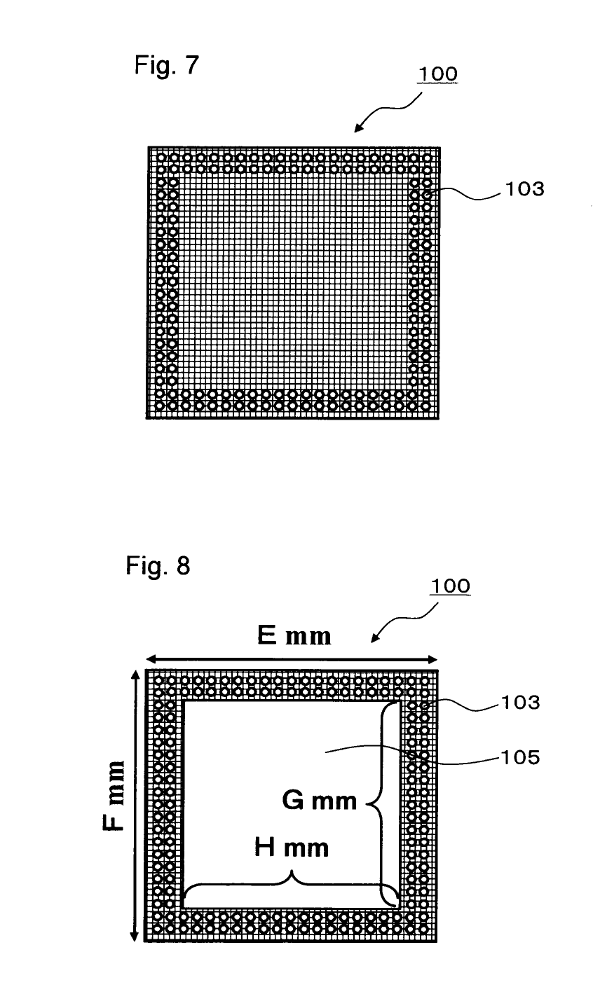

FIG. 7 is a plain schematic drawing showing the spacer sheet 100 of the present invention after providing through holes, and FIG. 8 is a plain schematic drawing showing the spacer sheet 100 of the present invention shown in FIG. 7 after punching work of a pattern corresponding to a principal part of a semiconductor package. A space part 105 is provided in the spacer sheet 100.

In FIG. 7, the through holes 103 are arranged in a double line, but they may be arranged in a single line or triplet lines. The spacer sheet 100 on which the through holes are provided is further subjected to punching work of a pattern corresponding to a principal part of the semiconductor package to provide the space part 105. In the punching work of the pattern, it is punched out by punching work according to a shape of a principal part 126 or 136 of the upper or lower semiconductor package. Assuming that an outer circumference is E mm×F mm and that an inner circumference (an outer circumference of the space part 105) is G mm×H mm, usually E and F are 5 to 50 mm, and G and H are 3 to 48 mm. The shape is approximately square in many cases.

Next, a production process for the complex type semiconductor device of the present invention shall be explained with reference to FIG. 9. FIG. 9 is a step schematic drawing of the production process of the present invention. FIG. 9-a shows a state prior to a step in which a connection terminal of a substrate in an upper semiconductor package is fused with a connection terminal of a substrate in a lower semiconductor package, and FIG. 9-b shows a state after finishing the step of fusing the above connection terminals. The respective steps of producing the complex type semiconductor device shown in FIG. 2 shall be explained below.

(1) a step in which in the spacer sheet 100 equipped with the adhesive layer 101 and the base material layer 102, the through holes 103 are provided in an array corresponding to the electrode 132 of the substrate 131 in the lower semiconductor package 13 and in which the space part 105 corresponding to the principal part of the lower semiconductor package is provided has been described above.
(2) Separately, in a step in which the connection terminal 142 is formed in the electrode 132 of the substrate 131 in the lower semiconductor package 13, after applying a flux on the electrode 132 by a screen printing method, a solder ball is set thereon, and it is put in an IR reflow (maximum temperature: 260° C., manufactured by Senju Metal Industry Co., Ltd.) to fuse the solder ball on the electrode 132, whereby the ball-shaped connection terminal 142 (bump) is formed.
(3) Further, also in a step in which the connection terminal 141 is formed in the electrode 112 of the substrate 111 in the upper semiconductor package 12, the ball-shaped connection terminal 141 (bump) is formed in the same manner as in (2). The upper semiconductor package 12 in which the connection terminal 141 is formed is shown in FIG. 9-a.
(4) After finishing the steps (1) and (2) described above, a step in which an adhesive layer 101 face of the spacer sheet 100 is stuck onto the substrate 131 in the lower semiconductor package 13 is carried out. In this respect, the spacer sheet 100 is opposed to the substrate 131, and the respective through holes 103 and the space part 105 in the spacer sheet 100 are fitted to the positions of the electrodes 132 and the position of the principal part 136 of the lower semiconductor package 13 mounted on the substrate 131 to insert the connection terminals 142 of the substrate 131 into the through holes 103, whereby the spacer sheet 100 is stuck onto the substrate 131.

In the above adhering step, a sheet on which many spacer sheets 100 shown in FIG. 8 are disposed is stuck in an integrated manner onto a body in which many lower semiconductor packages 13 are disposed, and then the sheet is cut off into individual semiconductor packages 13 by dicing, which is preferred from the viewpoint of enhancing the productivity.

(5) Lastly, after the connection terminal 141 of the substrate 121 in the upper semiconductor package 12 obtained by the step (3) is applied with a flux by a screen printing method, the above connection terminal 141 is put on the connection terminal 142 of the substrate 131 in the lower semiconductor package 13 obtained in the step (4) so that they are not out of alignment, and it is put in an IR reflow (maximum temperature: 260° C., manufactured by Senju Metal Industry Co., Ltd.) to fuse the above connection terminal 141 with the connection terminal 142, whereby the wiring connecting part 15 is formed.

In forming the wiring connecting part 15, the connection terminals 141 and 142 are fused and integrated when the spacer sheet 100 is not present, but they are apt to be spheroidized by a surface tension. Accordingly, not only a distance between the upper and lower semiconductor packages is less liable to be expanded, but also the risk that the adjacent wiring connecting parts are brought into contact and short-circuited is large. The presence of the spacer sheet 100 not only prevents the connection terminals 142 of the lower semiconductor package 13 from being brought into contact and short-circuited but also controls deformation of the fused connection terminals 141 in the upper semiconductor package 12 to a size of an aperture of the through holes 103 by a surface tension, and therefore it prevents a part exposed from the spacer sheet 100 from being expanded without restriction and prevents the connection terminals from being short-circuited.

Thus, using the spacer sheet 100 in the complex type semiconductor device 10 of the present invention makes it possible to satisfy securing of a height in a connection terminal distance and a narrow pitch at the same time.

The step (3) described above is carried out separately from the steps (1), (2) and (4) and may be carried out at any time before, after or in the middle of the above steps. Also, the step (2) may be carried out as well at any time before, after or in the middle of the step (1). Accordingly, the production process of the present invention shall not be restricted to the order described in item 3.

In the production process of the present invention, the sizes of the connection terminal 141 and the connection terminal 142 may be the same or different. An example in which the connection terminal 141 is large and in which the connection terminal 142 is small is shown in FIG. 9-a, but it may be inverse.

A material used for the connection terminals 141 and 142 formed in the electrodes 122 and 132 on the substrates 121 and 131 according to the present invention is preferably a solder ball. The solder ball can be selected from various solder compositions. It can widely be selected from, for example, a tin-silver eutectic solder and a tin-silver-copper eutectic solder each of which is a lead-free solder, a tin-lead eutectic solder and the like. A form of the solder ball is usually spherical. The solder ball has an average particle diameter of preferably 50 to 500 μm, particularly preferably 100 to 400 μm.

The best embodiment of the present invention has been explained above, but the present invention shall not be restricted to the above explanations and can assume various embodiments.

For example, the complex type semiconductor device in which the spacer sheet 100 is adhered on an upper surface of the substrate 131 of the lower semiconductor package 13 has been explained, but it may be the complex type semiconductor device in which the connection terminal 141 is adhered, as shown in FIG. 3, on a lower surface of the substrate 121 of the upper semiconductor package 12 so that the connection terminal is inserted thereinto. In the above case, the spacer sheet 100 is opposed to the substrate 121 in the adhering step, and the respective through holes 103 and the space part 105 in the spacer sheet 100 are fitted to the positions of the electrodes 141 and the position of the principal part 136 of the lower semiconductor package 13 opposed to the substrate 121 to insert the connection terminals 141 of the substrate 121 into the through hole 103, whereby the spacer sheet 100 is stuck onto the substrate 121.

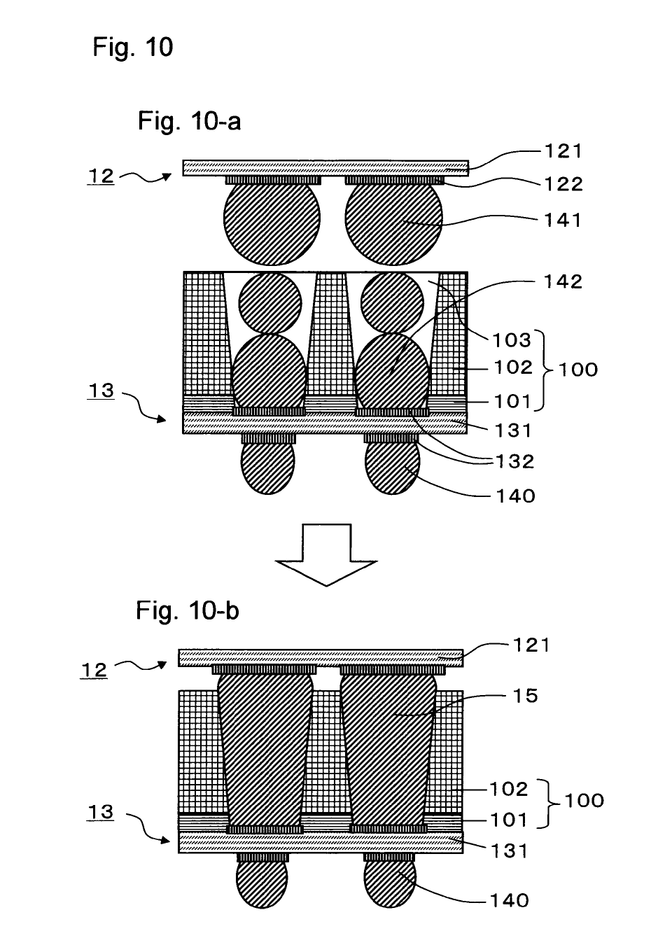

The connection terminals may be one set comprising a connection terminal 141 provided on a lower surface of the substrate 121 in the upper semiconductor package 12 and two connection terminals 142 provided on an upper surface of the substrate 131 in the lower semiconductor package 13. To be specific, when the spacer sheet 100 is thick as shown in FIG. 10, a plurality of 3 or more solder balls may be one set in the connection terminal. To be specific, another connection terminal (solder ball) is put, as shown in FIG. 10-a, on the connection terminal 142 inserted into the through hole 103 and subjected to IR reflow to integrate them, and then or the upper semiconductor package 12 is put directly on another connection terminal (solder ball) and subjected to IR reflow, and plural connection terminals can integrally be molded (refer to FIG. 10-b). The manner described above prevents the solder ball having a large diameter from being used as the connection terminal and prevents a distance between the substrates and a margin of a pitch between the connection terminals from being reduced by a diameter of the solder ball.

A periphery of the exposed connection terminal at a side which is not inserted into the through hole 103 may be filled with an underfill material. The manner described above increases a strength of the complex type semiconductor device and enhances an impact resistance thereof.

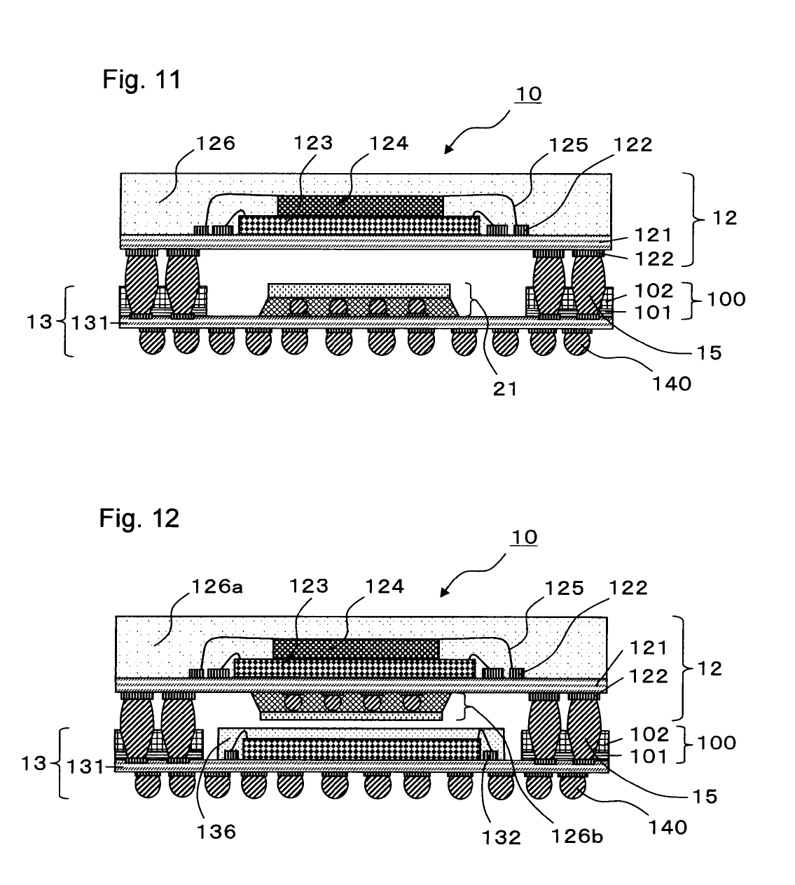

Further, in the explanations and the drawings described above, a principal part of the semiconductor package has been explained as a mold part of the semiconductor package including the semiconductor chip, and as shown in FIG. 11, a chip itself (flip chip 21) formed by subjecting to flip chip bonding on the substrate may be a principal part of the semiconductor package.

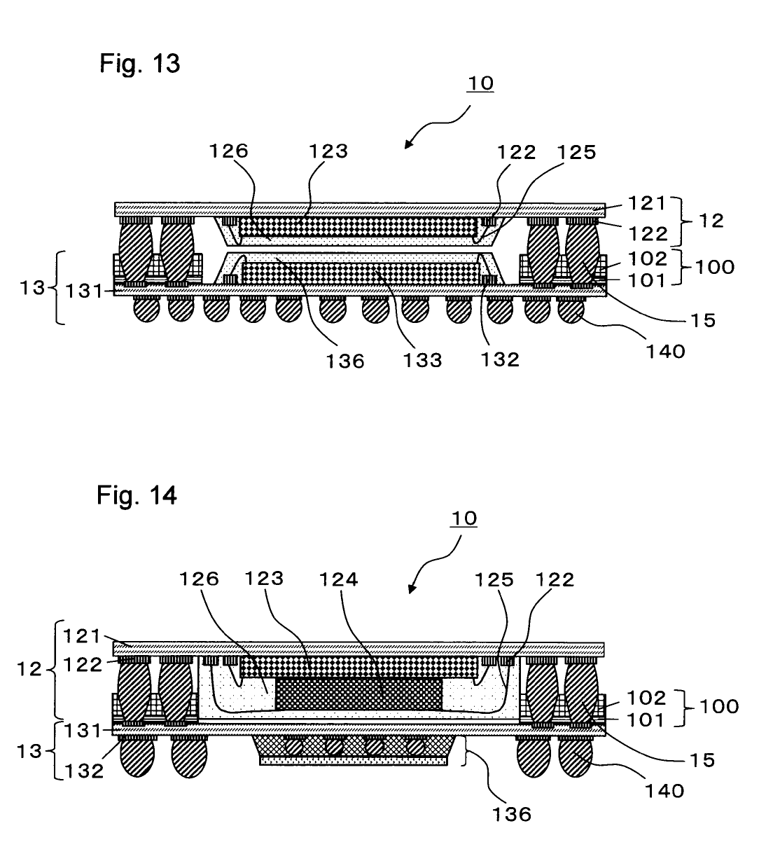

The upper semiconductor package 12 and the lower semiconductor package 13 assume a constitution in which both of the principal parts thereof are provided at an upper surface side of the substrate, and as shown in FIGS. 12 to 14, they may assume inversely a POP structure in which the principal parts are provided on a lower surface of the substrate. FIG. 12 shows a case in which the principal parts 126a and 126b of the upper semiconductor package 12 are disposed on both upper and lower surfaces and in which a principal part of the lower semiconductor package 13 is disposed on the upper surface. FIG. 13 shows a case in which the principal part of the upper semiconductor package 12 is disposed on the lower surface and in which the principal part of the lower semiconductor package 13 is disposed on the upper surface to allow the semiconductor packages to be opposed. FIG. 14 shows a case in which the principal parts of both the upper semiconductor package 12 and the lower semiconductor package 13 are provided on the lower surfaces. Also in the case of the POP structure shown in FIGS. 12 to 14 described above, the spacer sheet 100 is used between the substrates. In the above case, the spacer sheet 100 may be provided at a substrate 131 side of the lower semiconductor device 13 or a substrate 121 side of the upper semiconductor device 12. When the principal part is provided on a lower surface of the substrate 121 in the upper semiconductor package 12, a size of the above principal part is designed so that it is a size in which the principal part is inserted into the space part 105 of the spacer sheet 100.

### EXAMPLES

Next, the present invention shall be explained in further details with reference to examples, but the present invention shall by no means be restricted by these examples.

The possibility of electrical connection and a distance between the upper and lower substrates were measured according to the following methods.

### <Possibility of Electrical Connection>

Conduction between the probes of the upper and lower substrates was confirmed by means of a digital multimeter (3801 digital high tester, manufactured by HIOKI E.E. CORPORATION).

### <Distance Between Upper and Lower Substrates>

A cross section of the connection terminal part was allowed to appear by polishing a cross section of the complex type semiconductor device, and then a distance between the upper and lower substrates was measured by means of a digital microscope.

The following materials were used for the adhesive layers, the base material layers and the release films in Examples 1 to 8 and Comparative Examples 1 to 2.

### 1. Adhesive Layer:

### (1) Adhesive Layer α: Acryl Base Pressure-Sensitive Adhesive

A blended matter prepared by blending 100 parts by mass of an acryl base adhesive principal agent (Oribain BPS5375, manufactured by Toyo Ink MFG. Co., Ltd.) with 2 parts by mass of organic polyvalent isocyanate (Coronate L, manufactured by Nippon Polyurethane Industry Co., Ltd.) was applied on a polyethylene terephthalate film (SP-PET3811, manufactured by Lintec Corporation, thickness: 38 μm) in which one surface was subjected to release treatment, and then the applied film was dried at 90° C. for 2 minutes to obtain an adhesive layer α. The volume resistivity was 2×10¹⁴ Ω·cm.

### (2) Adhesive Layer β: Silicone Base Pressure-Sensitive Adhesive

A blended matter prepared by blending 100 parts by mass of an addition reaction type silicone adhesive principal agent (SD4580, manufactured by Dow Corning Toray Co., Ltd.) with 1 part by mass of a platinum catalyst (RX212, manufactured by Dow Corning Toray Co., Ltd.) was applied on a polyethylene terephthalate film (Filmbyna 38E-0010YC, manufactured by Fujimori Kogyo Co., Ltd., thickness: 38 μm) in which one surface was subjected to release treatment, and then the applied film was dried at 130° C. for 2 minutes to obtain an adhesive layer β. The volume resistivity was 8×10¹⁵ Ω·cm.

### (3) Adhesive Layer γ: Thermoplastic Adhesive

A thermally adhesive polyimide base resin (UL27, manufactured by Ube Industries, Ltd.) was applied on a polyethylene terephthalate film (SP-PET38AL-5, manufactured by Lintec Corporation, thickness: 38 μm) in which one surface was subjected to release treatment, and then the applied film was dried at 130° C. for 2 minutes to obtain an adhesive layer γ. The volume resistivity was 1×10¹⁵ Ω·cm.

### (4) Adhesive Layer δ: Thermosetting Adhesive

A blended matter of an acryl copolymer/a liquid epoxy resin A/a solid epoxy resin B/a solid epoxy resin C/a curing agent/a curing accelerating agent/a silane coupling agent/polyisocyanate=20/30/40/10/1/1/0.6/0.5 (unit: parts by mass) was applied on a polyethylene terephthalate film (SP-PET3811, manufactured by Lintec Corporation, thickness: 38 μm) in which one surface was subjected to release treatment, and then the applied film was dried at 90° C. for 2 minutes to obtain an adhesive layer δ. The volume resistivity was 7×10¹³ Ω·cm.

The respective materials used for the blended matter of the adhesive layer δ are shown below.

Acryl copolymer: COPONYL-2359-6, manufactured by Nippon Synthetic Industry Co., Ltd.

Liquid epoxy resin A: acryl rubber fine particle-dispersed bisphenol A type liquid epoxy resin (Eposet BPA328, manufactured by Nippon Shokubai Co., Ltd., epoxy equivalent: 230)

Solid epoxy resin B: bisphenol A type solid epoxy resin (Epikote 1055, manufactured by Japan Epoxy Resins Co., Ltd., epoxy equivalent: 875 to 975)

Solid epoxy resin C: o-cresol novolac type epoxy resin (EOCN-104S, manufactured by Nippon Kayaku Co., Ltd., epoxy equivalent: 213 to 223)

Curing agent: dicyandiamide (Adeka Hardener 3636AS, manufactured by Asahi Denka Co., Ltd.)

Curing accelerating agent: 2-phenyl-4,5-hydroxymethylimidazole (Curesol 2PHZ, manufactured by Shikoku Chemicals Corporation)

Silane coupling agent: MKC Silicate MSEP2, manufactured by Mitsubishi Chemical Corporation)

Polyisocyanate: Oribain BHS8515, manufactured by Toyo Ink MFG. Co., Ltd.

### 2. Base Material Layer:

The following materials were used for the base material layer.

(1) Base material layer α: polyimide film (Kapton 50EN, manufactured by Du Pont-Toray Co., Ltd., volume resistivity: 1×10¹⁵ Ω·cm.
(2) Base material layer β: polyimide film (UPILEX S-125, manufactured by Ube Industries, Ltd., volume resistivity: 1×10¹⁷ Ω·cm.

### 3. Release Film:

The following materials were used for the release film.

(1) Release film α: SP-PET3811, manufactured by Lintec Corporation, thickness: 38 μm.
(2) Release film β: Filmbyna 38E-0010YC, manufactured by Fujimori Kogyo Co., Ltd., thickness: 38 μm.
(3) Release film γ: SP-PET38AL-5, manufactured by Lintec Corporation, thickness: 38 μm.
4. Solder ball:

The following material was used for the solder ball for the connection terminals.

Lead-free solder (zinc-silver-copper): Eco Solder Ball M705, manufactured by Senju Metal Industry Co., Ltd., diameter: 250 μm, 300 μm, 450 μm.

### 5. Lower BGA Semiconductor Package:

The following package was used as the lower BGA semiconductor package.

Size: 14×14 mm, land number: 152, land pitch: 0.65 mm, land diameter: 300 μm, length from a land end to a package end: 350 μm, substrate thickness: 310 μm, mold height: 450 μm.

### 6. Upper BGA Semiconductor Package:

The following package was used as the upper BGA semiconductor package.

Size: 14×14 mm, land number: 152, land pitch: 0.65 mm, land diameter: 300 μm, length from a land end to a package end: 350 μm, substrate thickness: 310 μm, mold height: 450 μm.

### Example 1

a) The adhesive layer δ was applied on one surface of the base material layer α (50 μm) so that a thickness thereof after dried was 40 μm, and then it was dried at 90° C. for 2 minutes. Thereafter, the release film α was stuck on an exposed surface of the adhesive layer to prepare a sheet on which the base material layer α/the adhesive layer δ/the release film α were laminated.

Further, the adhesive layer δ was applied on one surface of another base material layer α so that a thickness thereof after dried was 40 μm, and it was dried at 90° C. for 2 minutes. Then, a base material layer face of the sheet described above was stuck on an exposed surface of the adhesive layer immediately after dried to obtain a sheet material [A] for a spacer sheet. The sheet material [A] assumed, as shown in FIG. 6, a five-layer structure described later and had a thickness of 180 μm excluding that of the release film α.

Layer structure: base material layer α (50 μm)/adhesive layer δ (40 μm)/base material layer α (50 μm)/adhesive layer δ (40 μm)/release film α (38 μm).
b) Next, through holes for inserting connection terminals were provided on the sheet material [A] in an array corresponding to electrodes of a substrate by means of a carbon dioxide gas laser irradiating machine (Lavia 1000TW, manufactured by Sumitomo Heavy Industries, Ltd.). The above through holes had, as shown in FIG. 6, a cone shape (through hole maximum diameter: 380 μm, through hole minimum diameter: 310 μm). A spacer sheet shown in FIG. 7 was obtained by providing the above through holes.
c) Then, a pattern of an outer periphery and a space part (outer periphery: 14×14 mm, space part (inner periphery): 11×11 mm) was provided by punching work to obtain a spacer sheet [A] shown in FIG. 8.
d) Separately, a flux was applied on an electrode formed on an upper surface of a substrate in a lower BGA semiconductor package by a screen printing method, and then a lead-free solder (diameter: 250 μm) was set thereon. The package was put in an IR reflow (maximum temperature: 260° C., manufactured by Senju Metal Industry Co., Ltd.) to form a connection terminal on the electrode of the package.
e) The spacer sheet [A] prepared in advance in c) from which the release film was peeled was opposed to the substrate of the lower BGA semiconductor package prepared in d) described above, and the respective through holes and the space part of the spacer sheet [A] were fitted to the positions of the electrodes and the position of the principal part of the lower semiconductor package mounted on the substrate. They were inserted and stuck (First Laminator UA-400III, manufactured by Taisei Laminator Co., Ltd., conditions: pressure 0.3 MPa, speed: 0.1 m/minute, temperature: 23° C.).
f) Next, the spacer sheet was put in a dryer at 160° C. for one hour in order to cure the adhesive layer in e).
g) Separately, a flux was applied on electrodes formed on a lower surface of a substrate in an upper BGA semiconductor package to be mounted on the upper part of the assembly through f) by a screen printing method, and then a lead-free solder (diameter: 450 μm) was set thereon. The package was put in an IR reflow (maximum temperature: 260° C., manufactured by Senju Metal Industry Co., Ltd.).
h) A flux was applied on the connection terminals formed in g) by a screen printing method, and then the upper BGA semiconductor package in g) was mounted on an upper part of the lower BGA semiconductor package equipped with the spacer sheet in d) and put in an IR reflow (maximum temperature: 260° C., manufactured by Senju Metal Industry Co., Ltd.) to connect the upper BGA semiconductor package with the lower BGA semiconductor package, whereby a complex type semiconductor device staying in a state of before connection terminals for an external electrode were formed was obtained. Possibility of electrical connection and a distance between the upper and lower substrates in the complex type semiconductor device thus obtained were measured. The results thereof are shown in Table 1.

### Example 2

A diameter of a lead-free solder for the upper BGA semiconductor package in Example 1 was changed from a diameter of 450 μm in Example 1 to a diameter of 300 μm, and a diameter of a lead-free solder for the lower BGA semiconductor package was changed from a diameter of 250 μm in Example 1 to a diameter of 450 μm. Further, the step g) was carried out in advance before the step e), and then the same procedure as in Example 1 was carried out, except that in the step e), the respective through holes and the space part in the spacer sheet [A] were opposed to the substrate of the upper BGA semiconductor package and fitted to the positions of the electrodes of the above substrate and the position of the principal part of the lower semiconductor package and that the above respective through holes were inserted into the connection terminals of the substrate in the upper BGA semiconductor package to stick them. Possibility of electrical connection and a distance between the upper and lower substrates in the complex type semiconductor device thus obtained were measured. The results thereof are shown in Table 1.

### Example 3

The adhesive layer β was applied on one surface of the base material layer β so that a thickness thereof after dried was 55 μm, and then it was dried at 130° C. for 3 minutes. Thereafter, the release film β was stuck on an exposed surface of the adhesive layer to prepare a sheet material [B] (a thickness was 180 μm excluding that of the release film β) in which a layer structure was the base material layer β (125 μm)/the adhesive layer β (55 μm)/the release film β (38 μm) as shown in FIG. 5. Steps subsequent to the above step were the same as in Example 1. The step f) in Example 1 was excluded. A spacer sheet [B] was prepared from the sheet material [B]. Possibility of electrical connection and a distance between the upper and lower substrates in the complex type semiconductor device thus obtained were measured. The results thereof are shown in Table 1.

### Example 4

A diameter of a lead-free solder for the upper BGA semiconductor package in Example 3 was changed from a diameter of 450 μm in Example 3 to a diameter of 300 μm, and a diameter of a lead-free solder for the lower BGA semiconductor package was changed from a diameter of 250 μm in Example 3 to a diameter of 450 μm. Further, the step g) was carried out in advance before the step e), and then the same procedure as in Example 3 was carried out, except that in the step e), the respective through holes and the space part in the spacer sheet [B] were opposed to the substrate of the upper BGA semiconductor package and fitted to the positions of the electrodes of the above substrate and the position of the principal part of the lower semiconductor package and that the above respective through holes were inserted into the connection terminals of the substrate in the upper BGA semiconductor package to stick them. Possibility of electrical connection and a distance between the upper and lower substrates in the complex type semiconductor device thus obtained were measured. The results thereof are shown in Table 1.

### Example 5

The adhesive layer δ (thermosetting adhesive) was applied on one surface of the release film α (38 μm) so that a thickness thereof after dried was 90 μm, and then it was dried at 130° C. for 3 minutes to prepare a sheet in which the adhesive layer δ was laminated on the release film α.

Next, the adhesive layer δ was applied on one surface of another release film α so that a thickness thereof after dried was 90 μm, and then it was dried at 90° C. for 2 minutes. An adhesive layer face of the sheet described above was stuck on an exposed surface of the adhesive layer immediately after dried to obtain a sheet material [C] in which the release film α (38 μm)/the adhesive layer δ (180 μm)/the release film α (180 μm) were laminated. Steps subsequent to the above step were the same as in Example 1. A spacer sheet [C] was prepared from the sheet material [C]. Possibility of electrical connection and a distance between the upper and lower substrates in the complex type semiconductor device thus obtained were measured. The results thereof are shown in Table 1.

### Example 6

A diameter of a lead-free solder for the upper BGA semiconductor package in Example 5 was changed from a diameter of 450 μm in Example 5 to a diameter of 300 μm, and a diameter of a lead-free solder for the lower BGA semiconductor package was changed from a diameter of 250 μm in Example 5 to a diameter of 450 μm. Further, the step g) was carried out in advance before the step e), and then the same procedure as in Example 5 was carried out, except that in the step e), the respective through holes and the space part in the spacer sheet [C] were opposed to the substrate of the upper BGA semiconductor package and fitted to the positions of the electrodes of the above substrate and the position of the principal part of the lower semiconductor package and that the above respective through holes were inserted into the connection terminals of the substrate in the upper BGA semiconductor package to stick them. Possibility of electrical connection and a distance between the upper and lower substrates in the complex type semiconductor device thus obtained were measured. The results thereof are shown in Table 1.

### Example 7

The adhesive layer α was applied on one surface of the base material layer β so that a thickness thereof after dried was 55 μm, and then it was dried at 90° C. for 2 minutes. Thereafter, the release film α was stuck on an exposed surface of the adhesive layer to prepare a sheet material [D] (a thickness was 180 μm excluding that of the release film α) in which the base material layer β (125 μm)/the adhesive layer α (55 μm)/the release film α (38 μm) in a layer structure were laminated as shown in FIG. 5. Steps subsequent to the above step were the same as in Example 1. The through holes of the sheet material [D] were provided by a drilling method to obtain a spacer sheet [D]. The step f) in Example 1 was excluded. Possibility of electrical connection and a distance between the upper and lower substrates in the complex type semiconductor device thus obtained were measured. The results thereof are shown in Table 1.

### Example 8

A diameter of a lead-free solder for the upper BGA semiconductor package in Example 7 was changed from a diameter of 450 μm in Example 7 to a diameter of 300 μm, and a diameter of a lead-free solder for the lower BGA semiconductor package was changed from a diameter of 250 μm in Example 7 to a diameter of 450 μm. Further, the step g) was carried out in advance before the step e), and then the same procedure as in Example 7 was carried out, except that in the step e), the respective through holes and the space part in the spacer sheet [D] were opposed to the substrate of the upper BGA semiconductor package and fitted to the positions of the electrodes of the above substrate and the position of the principal part of the lower semiconductor package and that the above respective through holes were inserted into the connection terminals of the substrate in the upper BGA semiconductor package to stick them. Possibility of electrical connection and a distance between the upper and lower substrates in the complex type semiconductor device thus obtained were measured. The results thereof are shown in Table 1.

### Example 9

The adhesive layer γ was applied on one surface of the base material layer β so that a thickness thereof after dried was 55 μm, and then it was dried at 130° C. for 3 minutes. Thereafter, the release film γ was stuck on an exposed surface of the adhesive layer to prepare a sheet material [E] (a thickness was 180 μm excluding that of the release film γ) in which the base material layer β (125 μm)/the adhesive layer γ (55 μm)/the release film γ (38 μm) in a layer structure were laminated as shown in FIG. 5. Steps subsequent to the above step were the same as in Example 1. A spacer sheet [E] was prepared from the sheet material [E]. Steps subsequent to the above step were the same as in Example 1. A spacer sheet [E] was prepared from the sheet material [E]. Provided that the spacer sheet [E] was stuck on the substrate of the lower semiconductor package under heating at 130° C. The step f) in Example 1 was excluded. Possibility of electrical connection and a distance between the upper and lower substrates in the complex type semiconductor device thus obtained were measured. The results thereof are shown in Table 1.

### Example 10

A diameter of a lead-free solder for the upper BGA semiconductor package in Example 9 was changed from a diameter of 450 μm in Example 9 to a diameter of 300 μm, and a diameter of a lead-free solder for the lower BGA semiconductor package was changed from a diameter of 250 μm in Example 9 to a diameter of 450 μm. Further, the step g) was carried out in advance before the step e), and then the same procedure as in Example 9 was carried out, except that in the step e), the respective through holes and the space part in the spacer sheet [E] were opposed to the substrate of the upper BGA semiconductor package and fitted to the positions of the electrodes of the above substrate and the position of the principal part of the lower semiconductor package and that the above respective through holes were inserted into the connection terminals of the substrate in the upper BGA semiconductor package to stick them. The spacer sheet [E] was stuck on the substrate of the upper semiconductor package under heating at 130° C. Possibility of electrical connection and a distance between the upper and lower substrates in the complex type semiconductor device thus obtained were measured. The results thereof are shown in Table 1.

### Comparative Example 1

The same steps as in Example 1 were carried out without using a spacer sheet. Accordingly, the procedure was carried out excluding the steps of a), b), c), e) and f) in Example 1. Possibility of electrical connection and a distance between the upper and lower substrates in the complex type semiconductor device thus obtained were measured. The results thereof are shown in Table 1.

### Comparative Example 2

The same procedure as in Comparative Example 1 was carried out, except that a diameter of a lead-free solder for the lower BGA semiconductor package in the step d) of Comparative Example 1 was changed from a diameter of 250 μm to a diameter of 300 μm. Possibility of electrical connection and a distance between the upper and lower substrates in the complex type semiconductor device thus obtained were measured. The results thereof are shown in Table 1.

TABLE 1

| | Possibility of | Distance between upper |
|---|---|---|
| | electrical connection | and lower substrates (μm) |
| Example 1 | OK | 483 |
| Example 2 | OK | 547 |
| Example 3 | OK | 476 |
| Example 4 | OK | 544 |
| Example 5 | OK | 480 |
| Example 6 | OK | 541 |
| Example 7 | OK | 479 |
| Example 8 | OK | 540 |
| Example 9 | OK | 480 |
| Example 10 | OK | 542 |
| Comparative | No | Brought into contact with |
| Example 1 | | mold of lower |
| | | semiconductor package |
| Comparative | No | Brought into contact with |
| Example 2 | | mold of lower |
| | | semiconductor package |

As shown in Table 1, connection between the upper and lower semiconductor packages was possible in all of Examples 1 to 10, and electrical connection was confirmed without causing problems of short circuit and the like.

Further, a distance (450 μm or more) between the substrates was secured without being brought into contact with the principal parts.

On the other hand, in both of Comparative Examples 1 and 2, the heights of the connection terminals run short as compared with the heights of the principal parts to make it impossible to bring the connection terminals of the upper and lower semiconductor packages into contact.

Further, in Comparative Example 2, short circuit between the adjacent connection terminals was brought about by an increase in a diameter of the connection terminals in fusing the solder after reflow.

### INDUSTRIAL APPLICABILITY

The spacer sheets, the sheet materials and the production process for a complex type semiconductor device in which the same is used according to the present invention make it possible to carry out stable electrical connection in the POP type semiconductor packages and are suitably used for producing various complex type semiconductor devices. A complex type semiconductor device obtained by using the same has a high packaging density and is suitably used as a part for various computers, portable phones, various mobile devices and the like.

1. A spacer sheet for a complex type semiconductor device provided between the semiconductor packages of a complex type semiconductor device formed by laminating plural semiconductor packages, comprising through holes of an array corresponding to electrodes which can be provided onto a substrate of one semiconductor package and which are formed on the above substrate in order to connect and wire one semiconductor package with the other semiconductor package and a space part corresponding to a principal part of the above one semiconductor package mounted on the substrate or a principal part of the other semiconductor package opposed to the substrate.

2. The spacer sheet for a complex type semiconductor device according to claim 1, wherein the through holes of the spacer sheet are cone-shaped.

3. A sheet material used for the spacer sheet for a complex type semiconductor device according to claim 1.

4. A semiconductor package used for a complex type semiconductor device formed by laminating plural semiconductor packages, comprising a principal part of the above semiconductor package, a substrate on which the above principal part is mounted and which has a broader area than that of the principal part, an electrode provided on a surface of the above substrate at a side which is connected and wired with the other semiconductor package, a spacer sheet which has through holes of an array corresponding to the above electrode and which is adhered on a surface of the above substrate at a side connected and wired with the other semiconductor package and a connection terminal provided on the above electrode in the state that it is inserted into the through hole.

5. A production process for a complex type semiconductor device formed by laminating plural semiconductor packages, comprising:
a step in which a connection terminal is formed on an electrode provided on a substrate of one semiconductor package and used for conducting with the other semiconductor package,
a step in which through holes in an array corresponding to the electrodes and a space part corresponding to a principal part of the one semiconductor package mounted on the substrate or a principal part of the other semiconductor package opposed to the above substrate are provided on a sheet material capable of being adhered onto the above substrate to prepare a spacer sheet,
a step in which the spacer sheet is opposed to the substrate and in which the respective through holes and the space part in the spacer sheet are fitted to the positions of the electrodes and the position of the principal part of the one semiconductor package mounted on the substrate or the principal part of the other semiconductor package opposed to the substrate to adhere the spacer sheet to the substrate,
a step in which a connection terminal is formed on the electrode of the substrate in the other semiconductor package and
a step in which the connection terminal of the substrate in the one semiconductor package is fused with the connection terminal of the substrate in the other semiconductor package.

6. The production process according to claim 5, wherein the through holes are provided in a cone shape.

7. A complex type semiconductor device produced by the production process according to claim 5.
